(19) United States
(12) Patent Application Publication
(10) Pub. No.: US 2007/0164753 A1
(43) Pub. Date: Jul. 19, 2007

(54) Power supply history monitor

(75) Inventors: George E. Smith III, Wappingers Falls, NY (US); Michael A. Sperling, Poughkeepsie, NY (US)

Correspondence Address: INTERNATIONAL BUSINESS MACHINES CORPORATION, IPLAW DEPARTMENT, 2455 SOUTH ROAD - MS P386, POUGHKEEPSIE, NY, 12601, US

(73) Assignee: International Business Machines Corporation, Armonk, NY (US)

(21) Appl. No.: 11/334,257

(22) Filed: Jan. 18, 2006

(51) Int. Cl. G01R 29/26

(52) U.S. Cl. 324/613

(57) ABSTRACT

A power supply history monitor. The monitor receives a short duration anomalous signal, e.g., from a power supply, and produces a digitized signal representing the anomalous signal as an output. The monitor receives a signal from a signal input, and includes an analog delay element in series with the signal input, a sample and hold element receiving a signal from the analog delay element, an analog signal processor receiving an output of the sample and hold element, and an analog to digital converter receiving an analog output of the analog signal processor. The output of the power supply history monitor is a digital output.

### BACKGROUND

1. Field of the Invention

A monitor for detecting power supply noise, and producing a digital output signal that is representative of the power supply noise.

2. Background Art

Microelectronic circuits are highly sensitive to power supply anomalies. For example, a voltage spike in a power supply to a circuit containing a phase lock loop or an oscillator can lock up the phase lock loop or oscillator. As an aid to trouble shooting, diagnostics, and design, a need exists to detect, capture, digitize, and characterize the noise.

This is particularly severe with short duration and high frequency noise.

### SUMMARY OF THE INVENTION

These problems are obviated by the power supply history monitor described herein. The power supply history monitor provides non-invasive on-chip detection and capture of power supply noise, and specifically of high frequency noise that is beyond the control of off-chip power supply feedback.

The power supply history monitor uses an analog delay line to delay the value of the input. The input may be either the power supply voltage or a divided down power supply voltage. Sample and hold circuits are set to capture the data along the analog delay line.

The sample and hold circuits can be triggered either externally, internally through a clock or test signal, or by logic that can detect when a significant noise event has occurred.

Once captured, this data can be converted to a digital signal and thereafter observed using low frequency test equipment. This enables obtaining a precise representation and understanding of the noise, for example, for subsequent design or a filtering network or of an improved power supply.

### THE FIGURES

Various aspects of the invention are illustrated in the Figures appended hereto.

FIG. 1 illustrates a high level circuit diagram for one embodiment of the power supply history monitor of our invention.

FIG. 2 illustrates an op-amp embodiment of an analog delay element.

### DETAILED DESCRIPTION

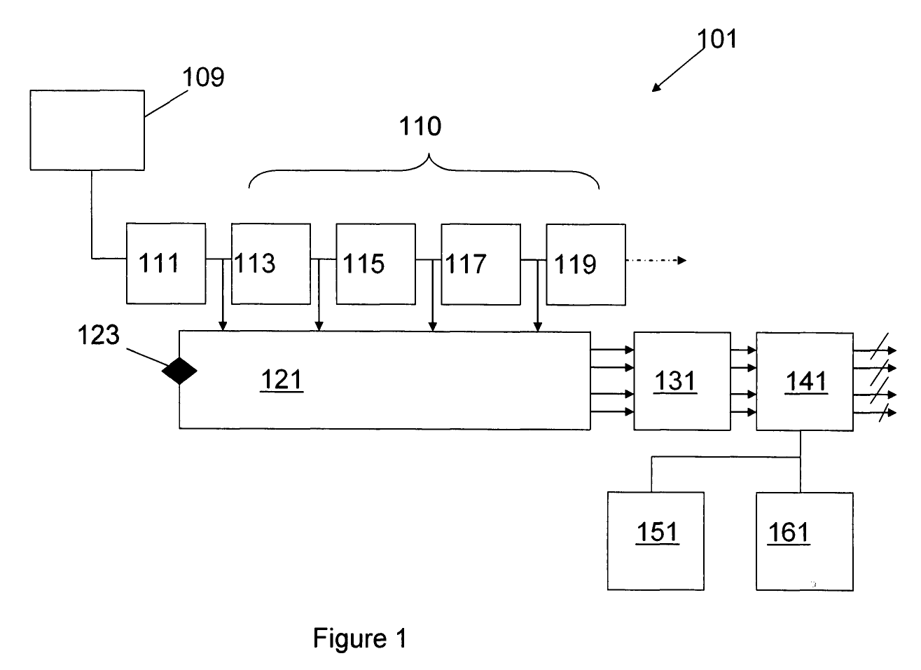

FIG. 1 illustrates a high level diagram of the Power Supply History Monitor described herein.

The Power Supply History Monitor 101 includes an analog delay line 110 composed of a series of analog delay elements, 113, 115, and 117, and 119. This delay line 110 is tapped off at regular intervals into multiple sample and hold elements. The gating signal 123 for the individual elements, both analog delay elements, 113, 115, and 117, and 119, and the sample and hold elements 121 comes from an external pin, internal logic, or circuitry that pulses when a noise event occurs.

Typical noise events captured by the power supply history monitor 101 might be a parity failure, an ECC trigger, a spike, radio frequency interference picked up by the supply. and the like.

The plurality of analog delay elements 113, 115, 117, and 119 are electrically in series from the power supply 109, with current flowing from the power supply 109 to the analog delay elements 113, 115, 117, and 119, in sequence, and with a measurement, as voltage, from each individual analog delay element, 113, 115, 117, and 119, in parallel to the sample and hold 121.

The analog data transferred to the sample and hold element 121 can be translated to the digital domain, for example through analog signal processors 131 and an analog to digital converter 141. This analog to digital conversion can be carried out at low frequency since the data has already been captured, and therefore is not sensitive to the speed of the converter. The speed of the analog to digital converter 141 is very slow compared to the duration of the noise.

The input level shifter 111 may be present if there is only one power supply 109 available. If, however, a second power supply is available at a higher voltage, and thus one can drive the rest of the circuitry, the power supply can be a direct input to the analog delay line 110.

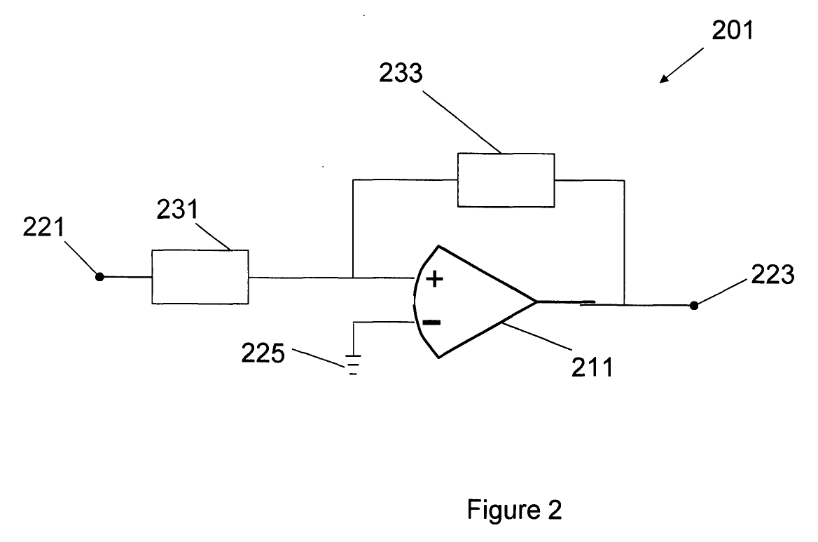

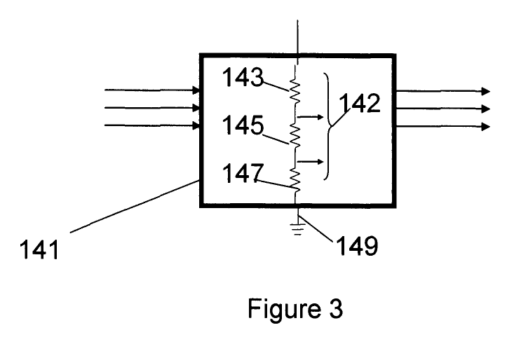

Exemplary analog delay elements can be as simple as an analog inverter, for example, a simple inverter or an operational amplifier network. One such op-amp inverter is illustrated in FIG. 2.

FIG. 2 is a schematic diagram illustrating a simple, high level op-amp inverter 201. The circuit includes an op-amp 211 with input 221, output 223, and ground 225. There are resistors 231 and 233. The inverting op-amp behaves as an analog delay element useful in providing the analog delay elements 113, 115, 117, and 119 of the invention.

Analog signal processors may be operational amplifier circuits or networks, for example an analog adder network.

Analog to digital converters useful in the invention are exemplified by resistor series networks, with voltage nodes between sequential resistors.

The power supply history monitor may be on the chip, or on an associated circuit board or card. The digitized output may be stored in associated memory, or transmitted in real time to a monitor.

While the invention has been described with respect to certain preferred embodiments and exemplifications, it is not intended to limit the scope of the invention thereby, but solely by the claims appended hereto.

1. A power supply history monitor for a microelectronic circuit comprising a power supply high frequency noise signal input, an analog inverter analog delay element in series with the signal input, a sample and hold element receiving a signal from the analog delay element, an operational amplifier analog signal processor receiving an output of the sample and hold element, and an analog to digital converter receiving an analog output of the analog signal processor and producing a digital output therefrom, said power supply history monitor on a chip with the microelectronic circuit.

2. The power supply history monitor of claim 1 wherein the output is captured in memory and stored.

3. The power supply history monitor of claim 1 wherein the output is transmitted to a display monitor.

4. The power supply history monitor of claim 1 wherein the analog delay element comprises an inverter.

5. The power supply history monitor of claim 1 wherein the analog signal processor comprises one or more operational amplifiers.

6. The power supply history monitor of claim 1 wherein the analog to digital converter comprises a resistor network.
